(19) United States
(12) Patent Application Publication
(10) Pub. No.: US 2014/0319981 A1
(43) Pub. Date: Oct. 30, 2014

(54) Thinned Housing Structure and Manufacturing Thereof

(71) Applicant: Sian-Ji JHANG, Taipei (TW)

(72) Inventor: Sian-Ji JHANG, Taipei (TW)

(21) Appl. No.: 13/922,600

(22) Filed: Jun. 20, 2013

(30) Foreign Application Priority Data
Apr. 24, 2013 (TW) 102114664

(51) Int. Cl. H05K 5/04; B21C 35/04; B21C 23/01

(52) U.S. Cl. CPC H05K 5/04; B21C 23/01; B21C 35/04
USPC 312/223.1; 72/255

(57) ABSTRACT

A thinned housing structure and manufacturing method to arrange a housing rough blank in a mold with multiple discharge ports provided at the bottom; press the housing rough blank with a high pressure press forming method such that residual material of the housing rough blank flowed through the discharge ports may form hosing rough blank flowing material for the area of the housing rough blank corresponding to the position of the discharge ports is not squeezed completely to form a large density second stress block, in addition, the area of the housing rough blank not corresponding to the position of the discharge ports are squeezed completely to form a small density first stress block; and perform a planarization work for the housing rough blank flowing material formed from the housing rough blank.

### BACKGROUND

1. Field of the Invention

The invention relates to a thinned housing structure and manufacturing method thereof, particularly to arrange a housing rough blank in a mold with multiple discharge ports provided at the bottom, utilize a high pressure press forming method for the housing rough blank to flow a housing rough blank flowing material through the discharge ports, such that an area of the housing rough blank corresponding to a position of the discharge ports is not squeezed completely to form a large density second press block, and an area of the housing rough blank corresponding to a position of the discharge ports are squeezed completely to form a small density first press block to achieve an integral housing with an intersected arrangement with large stress first press block and small press second press block, such that the housing have both improved overall strength and toughness to manufacture a housing structure with lighter and thinner thickness.

2. Descriptions of the Related Art

With the maturity of electronic technology development, current electronic devices are widely used. However, as for portable electronic devices (for example, notebook, tablet or intelligent mobile communication devices), the major resort is to be light, thin, robust and durable for consumers to carry easily. Thus, a housing structure suing metal alloy (for example, other metal alloys of aluminum, magnesium or titanium etc.) as material has been developed for current electronic devices. The major reason is because the housing structure made of metal alloy has properties of light weight, good thermal conductivity and EMI proof Hence, the housing structure made of metal alloy has been adopted gradually by manufacturers of electronic devices.

However, as for the housing made of metal alloy, for example the housing made of magnesium alloy, the major manufacturing approach is pressure casting. It is mainly to place the magnesium alloy substrate in a mold for pressure casting. Further, the forming difficulty is relatively high for thinner housing. The major reason is that as a housing has thinner pressure casting, the housing may suffer from problems such as heat crack, oxidation, flow liner, insufficient strength (stress) or deformation, causing low yield for the housing made of metal alloy. Besides, as there is the above poor product situation for the housing made of metal alloy, finishing procedures such as patching should be performed for poor housings in manually and thus increase man power and manufacturing cost.

Moreover, conventional technologies also use pressure forming to form a metal housing. However, the forming difficulty is relatively high for thinner housings by the pressure forming method. The main reason is that as the high pressure pressing is performed for a metal substrate in a closed mold, the pressure on the surface of the metal substrate is larger if the thickness of the preset pressing metal substrate is thinner, once the durable extensibility of the metal substrate is exceeded, the metal housing is easily to have crack and even broken to reduce the yield of the housing made of metal alloy.

### SUMMARY OF THE INVENTION

In order to figure out above problems and shortages of conventional technologies, the invention discloses a manufacturing approach for a thinned housing structure, which arranges a housing rough blank in a mold with multiple discharge ports provided at the bottom; utilizes a high pressure press forming method to press the housing rough blank, for residual material of the housing rough blank flowed through the discharge ports to form housing rough blank flowing material, such that an area of the housing rough blank corresponding to a position of the discharge ports is not squeezed completely to form a large density second press block, while an area of the housing rough blank not corresponding to a position of the discharge ports is squeezed completely to form a small density first press block; and performs a planarization work for the housing rough blank flowing material formed from the housing rough blank to form a housing. Thereby, an intersected arrangement of the housing with the press of the first stress block larger than that of the second stress block is utilized to for the housing to have an overall strength improved and toughness such that the manufacturing of a lighter and thinner housing structure is achieved.

The invention discloses a thinned housing structure, said housing is formed integrally by at least one metal material in a high pressure press forming method, the housing has a base, around which there are multiple side walls, and the base is provided with multiple first stress blocks and multiple second stress blocks, said first stress blocks and said second stress blocks are in interleaved arrangement, wherein the stress of the first stress block is larger than that of the second stress block. Thereby, with strength of the housing entirety enhanced relatively due to larger stress of the first stress blocks and the toughness due to smaller stress of the second stress blocks, the housing has both overall strength improved and toughness to achieve a housing thickness (that is the base thickness of the housing) may be manufactured more lighter and thinner, and at the same time, to reduce necessary material amount for the housing, and thereby to reduce the necessary cost of the housing.

### BRIEF DESCRIPTION OF THE DRAWINGS

FIG. 1 is a partial sectional view of an appearance of a housing structure according to the invention;

FIG. 2 is a schematic view showing an implementation of a first process for a housing structure according to the invention;

FIG. 3 is a schematic view showing an implementation of a second process for a housing structure according to the invention;

FIG. 4 is a schematic view showing an implementation of a third process for a housing structure according to the invention;

FIG. 5 is a schematic view showing an implementation of a fourth process for a housing structure according to the invention;

FIG. 6 is a partially enlarged schematic view indicating A in FIG. 5 according to the invention; and

FIG. 7 is a process flow chart of a housing structure according to the invention.

### DETAILED DESCRIPTION OF THE PREFERRED EMBODIMENT

For the examiner to understand other characteristic contents and advantages of the invention conveniently and clearly and the achieved effects thereof, the invention is stated in detail in connection with appended drawings in the following examples showing aspects of the invention in further detail, but limiting the scope of the invention.

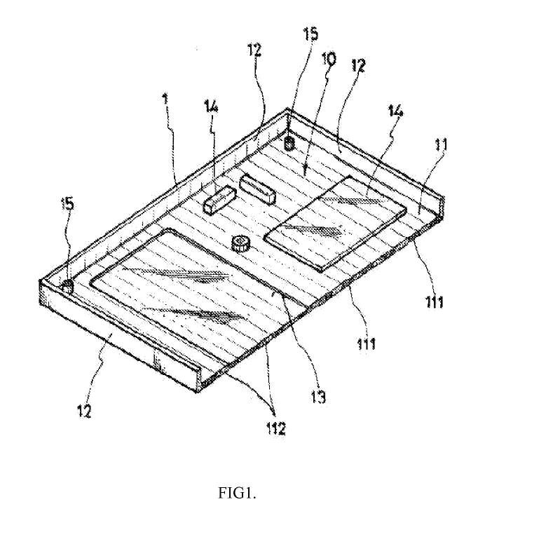

The invention discloses a thinned housing structure and manufacturing approach thereof. Refer to FIG. 1, which is a partially cross sectional view of an appearance of the thinned housing structure according to the invention. A housing 1 may be formed of at least a metal material integrally in a high pressure press forming method, and may be combined with a preset electronic device. The housing 1 has a base 11, around which multiple side walls 12 are provided. A holding space 10 is composed of the base 11 and the side walls 12, and the base 11 is provided with multiple first stress blocks 111 and multiple second stress blocks 112. The first stress blocks 111 and the second stress blocks 112 are in interleaved arrangement, wherein the density of the first stress blocks 111 is smaller than that of the second stress blocks 112 such that the stress (strength) of the first stress blocks 111 is larger than that of the second stress blocks. Further, at least a groove 13, at least a projection portion 14 and at least a joint portion 15 may be preset on the base 11 of the housing 1 opposite to the holding space 10.

The housing 1 has larger stress because of the smaller density of the first stress blocks 111 formed by the base 11 such that the overall strength of the housing 1 may be enhanced relatively. Besides, with the smaller stress due to the larger density of the second stress blocks 112 formed by the base 11, the second stress blocks 112 have toughness. By the interleaved arrangement of the first stress blocks 111 and the second stress blocks 112, the housing 1 has dual effects of improved overall strength and toughness, so that the thickness (that is, the thickness of the base 11 of the housing 1) of the housing 1 may be formed to be lighter and thinner such that the necessary material necessary for the housing 1 may be reduced to reduce the necessary cost of the housing 1.

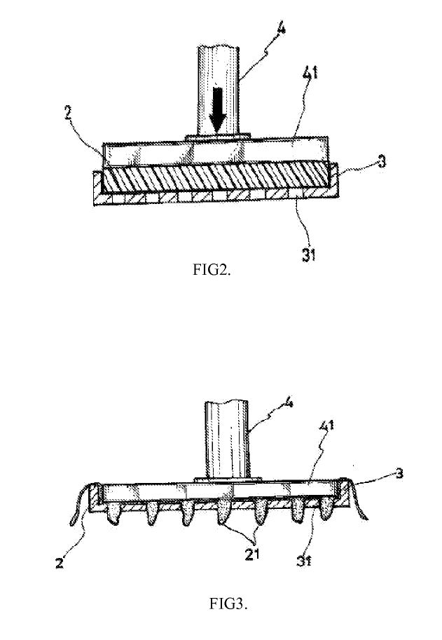

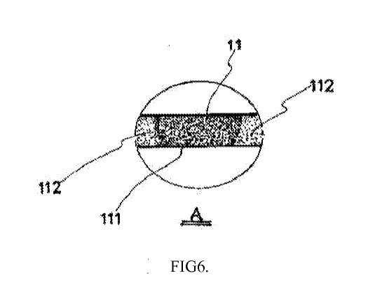

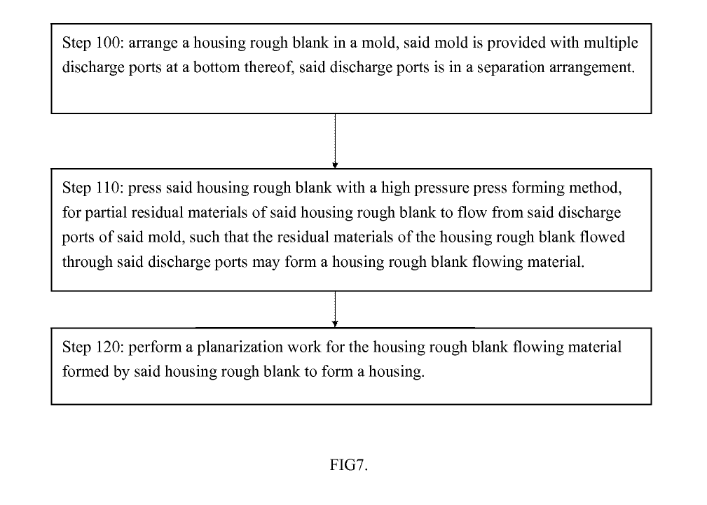

Further, refer to FIG. 2 to FIG. 7, the thinned housing 1 disclosed in the invention may be formed with the following process approach. The procedure of the process approach of the thinned housing according to the invention includes:

Step 100: provide a housing rough blank 2 in a mold 3 (as shown in FIG. 2), at the bottom of which provided are multiple discharge ports 31, which are arranged in separation. The discharge ports 31 may be in longitudinal separation arrangement. The discharge ports 31 may be in transverse separation arrangement. The discharge ports 31 may be in separation arrangement interleaved longitudinally and transversely.

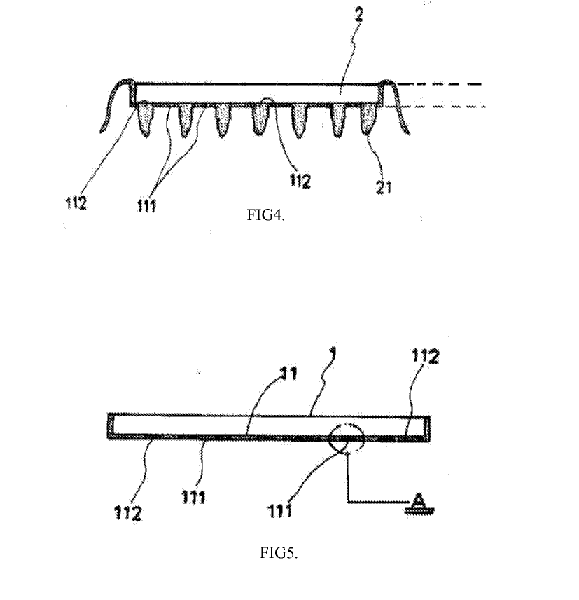

Step 110: press a housing rough blank 2 with the high pressure press forming method for partial residual materials of the housing rough blank 2 to flow from the discharge ports 31 of a mold 3 such that the residual materials of the housing rough blank 2 flowed from the discharge ports 31 may form a housing rough blank flowing material 21. In the high pressure press forming process, a preset pressure is applied to the housing rough blank 2 in the mold 3 by a press portion 41 of a high pressure press device 4, the housing rough blank 2 is squeezed by the press portion 41 of the high pressure press device 4 such that partial residual materials of the housing rough blank 2 flow from the discharge ports 31 of the mold 3, while the residual materials of the housing rough blank 2 flowed through the discharge ports 31 may form the housing rough blank flowing material 21, subsequently, the housing rough blank 2 is extracted from the mold 3 as shown in FIG. 3 and FIG. 4); wherein, an area (that is a block of the housing rough blank flowing material 21) of the housing rough blank 2 corresponding to a position of the discharge ports 31 is not squeezed completely to form a large density second press block 113, and additionally, an area (that is, a block not belongs to the housing rough blank flowing material 21) of the housing rough blank 2 not corresponding to a position of the discharge ports 31 is squeezed completely to form a small density first press block 111.

Step 120: perform a planarization work on the housing rough blank flowing material 21 formed by the housing rough blank 2 to form a housing 1. The planarization work may utilize a milling method to remove the housing rough blank flowing material 21 formed by the housing rough blank 2 and other residual materials, and thereby to form the thinned housing 1 disclosed in the invention (as shown in FIG. 5).

The manufacturing approach of a thinned housing according to the invention is by arranging a housing rough blank 2 in a mold 3 provided with multiple discharge ports 31 at a bottom, pressing the housing rough blank 2 with a high pressure press forming method, for residual materials of the housing rough blank 2 flowed through the discharge ports 31 to form a housing rough blank flowing material 21, using an area of the housing rough blank 2 corresponding to a position of the discharge ports 31 to form a housing rough blank flowing material 21, such that an area of the housing rough blank 2 corresponding to a position of the discharge ports 31 is not squeezed completely to form a large density second press block 112, subsequently, an area of the housing rough blank 2 corresponding to a position of the discharge ports 31 cannot flow out to form a housing rough blank flowing material 21, such that an area of the housing rough blank 2 not corresponding to a position of the discharge ports 31 is squeezed completely to form a small density first stress block 111, then, milling the housing rough blank flowing material 21 of the housing rough blank 2 and other residual materials to form a housing 1. Wherein, a base of the housing 1 may form multiple small density first stress blocks 111, and form multiple large density second stress block 112, the first stress blocks 111 formed by the base 11 have larger stress due to smaller density such that overall strength of the housing 1 may be enhanced relatively; besides, the second stress blocks 112 formed through the base 11 have smaller stress due to larger density such that the second stress blocks 112 have toughness, by utilizing an interleaved arrangement of the first stress blocks 111 and the second stress blocks 112, the housing 1 has dual effects of improved overall strength and toughness such that it achieves that the thickness (that is, the thickness of the base 11 of the housing 1) of the housing 1 may be pressed to be lighter and thinner, and concurrently materials necessary for the housing 1 may be reduced to reduce cost necessary for the housing 1.

An outer surface of the base 11 of the housing 1 may be provided with embossing pattern, or the outer surface of the base of the housing 1 may be sprayed with color or picture; additionally, the housing rough blank 2 and the housing 1 are at least one metal material (for example, other metal alloys of aluminum, magnesium, or titanium).

Although one possible example of the invention is embodied with above detailed description, the example is not used to limit the invention, but any implementation or change without departing from the spirit of the art of the invention should be included in claims of the application.

### NUMERALS

1 housing
10 holding space
11 base
111 first stress block
112 second stress block
12 side wall
13 groove
14 projection portion
15 joint portion
2 housing rough blank
21 housing rough blank flowing material
3 mold
31 discharge port
4 high pressure press device
41 press portion

What is claimed is:

1. A manufacturing method of a thinned housing comprising:
arrange a housing rough blank in a mold, said mold has provided with multiple discharge ports at a bottom thereof, said discharge ports is in separation arrangement;
said housing rough blank is pressed with a high pressure press forming method, in said high pressure press forming process, partial residual materials of said housing rough blank flows from said discharge ports of said mold, while residual materials of said housing rough blank flowed from said discharge ports may form a housing rough blank flowing material, such that an area of said housing rough blank corresponding to a position of said discharge ports forms a large density second stress block, and an area of said housing rough blank corresponding to a position of said discharge ports forms a small density first stress block; and
said housing rough flowing material formed by said housing rough blank is performed with a planarization work to form a housing, the stress of the first stress block of said housing is larger than that of the second stress block.

2. The manufacturing approach of a thinned housing of claim 1, wherein said planarization work may utilize a milling method to remove the housing rough blank flowing material formed by said housing rough blank.

3. The manufacturing approach of a thinned housing of claim 1, wherein said housing rough blank is at least a metal material.

4. The manufacturing approach of a thinned housing of claim 3, wherein said metal material may be other metal alloy of aluminum, magnesium, or titanium etc.

5. A thinned housing structure, said housing has a base, around which multiple side walls are formed, a holding space is formed oppositely by said base and said side walls, and said base is provided with multiple first stress blocks and multiple second stress blocks, said first stress blocks and said second stress blocks are in an interleaved arrangement, wherein the density of said first stress blocks is smaller than that of said second stress blocks, such that the stress of said first stress blocks is larger than that of the second stress blocks.

6. The thinned housing structure of claim 5, wherein said base of said housing may be provided relatively with at least a groove in the holding space.

7. The thinned housing structure of claim 5, wherein said base of said housing may be provided relatively with at least a projection portion in the holding space.

8. The thinned housing structure of claim 5, wherein said base of said housing may be provided relatively with at least a joint portion in the holding space.

9. The thinned housing structure of claim 5, wherein an outer surface of said base of said housing may be provided with a embossing pattern.

10. The thinned housing structure of claim 5, wherein an outer surface of said base of said housing may be sprayed with a color or a picture.
